(19) United States
(12) Patent Application Publication
(10) Pub. No.: US 2015/0327391 A1
(43) Pub. Date: Nov. 12, 2015

(54) SUPPORT RACK FOR WIRELESS ELECTRONIC DEVICES

(71) Applicant: ZIPPY TECHNOLOGY CORP., New Taipei City (TW)

(72) Inventor: Chin-Wen CHOU, New Taipei City (TW)

(73) Assignee: ZIPPY TECHNOLOGY CORP., New Taipei City (TW)

(21) Appl. No.: 14/273,978

(22) Filed: May 9, 2014

(51) Int. Cl. H05K 7/16; F16M 11/04; F16M 11/10

(52) U.S. Cl. CPC H05K 7/16; F16M 11/10; F16M 11/041

(57) ABSTRACT

A support rack for a wireless electronic device is installed on a keyboard through which keying commands are input, and is integrally fabricated from a plastic sheet. The support rack includes a positioning segment, a bearing segment and a support segment. The positioning segment is connected to the keyboard and includes a holding zone to hold a wireless electronic device. The bearing segment is connected to one side of the positioning segment opposite to the keyboard and includes at least one retaining portion. The support segment includes a leaning section which is connected to the side of the positioning segment opposite to the keyboard via a first folding notch, and a holding section which is connected to the leaning section via a second folding notch and coupled with the retaining portion to support for the support rack.

### FIELD OF THE INVENTION

The present invention relates to a support rack and particularly to a support rack installed on a keyboard to hold a wireless electronic device.

### BACKGROUND OF THE INVENTION

With flourishing development of wireless mobile technology wireless electronic devices are widely used in people's daily life these days. Through the wireless electronic devices people can receive and send e-mails, watch video programs or enjoy entertainments anytime. However, during use of the wireless electronic devices users often have to maintain same posture to watch the information displayed on the wireless electronic devices for a prolonged period of time. This could cause discomfort, such as soreness on users' neck, shoulders or hand muscles.

To address the aforesaid problem, support racks specially made for the wireless electronic devices have been developed by some producers. For instance, Taiwan patent No. M299420 discloses a mobile phone rack which includes a base, a lid capable of turning against the base and a slide capable of turning against the lid. The base, lid and slide are coupled together through a pivotal structure which can transform the mobile phone rack between a storage state and a support state. However, because the pivotal structure of the mobile phone rack includes several components, many process steps are needed in assembly, hence it is unfavorable for mass production. In addition, the mobile phone rack is not a part of the wireless electronic device. Users have to carry it with the wireless electronic device wherever they go, thus make use of the mobile phone rack very inconvenient.

To overcome the drawback of inconvenience of the aforesaid mobile phone rack, a support rack which also provides protective cover function has been developed, such as Taiwan patent No. M435656. It discloses a support rack for a keyboard that includes a body, a coupling portion, a first support portion and a second support portion. The coupling portion has one end hinged on the bottom side of the body and another end hinged on a keyboard. The first support portion is hinged on a first lateral side of the body, while the second support portion is hinged on a second lateral side of the body. When the keyboard is placed on a surface, the body can be flipped toward a first direction remote from the keyboard, and the first and second support portions also can be flipped toward the first direction until one lateral side of the first support portion leans on a lateral side of the second support portion and lower edges of the first and second support portions also abut the flat surface, so as to transform the support rack into a support state. Although the support rack seems to have an integrated structure, it actually is formed by multiple boards, including a rigid support board. The support rack has a flipping zone defined by the support board. During fabrication and assembly processes, those boards of the support rack have to be aligned precisely to make the support rack to be flipped and used normally.

### SUMMARY OF THE INVENTION

The primary object of the present invention is to solve the problem of the conventional support racks that is difficult in assembly and inconvenient for utilization.

To achieve the foregoing object the present invention provides a support rack for a wireless electronic device that is installed on a keyboard through which keying commands are input. The support rack is integrally fabricated from a plastic sheet. The support rack includes a positioning segment, a bearing segment and a support segment. The positioning segment connects to the keyboard and includes a holding zone to hold a wireless electronic device. The bearing segment is connected to one side of the positioning segment opposite to the keyboard and includes at least one retaining portion formed thereon. The support segment includes a leaning section which is connected to the side of the positioning segment opposite to the keyboard through a first folding notch for the wireless electronic device to rest, and a holding section which is connected to the leaning section via a second folding notch and coupled with the retaining portion to support for the support rack.

In one embodiment the leaning section of the support segment is located at two sides of the positioning segment opposite to the keyboard.

In another embodiment a sum of widths of the positioning segment and the support segment is equal to a width of the bearing segment.

In yet another embodiment a sum of widths of the bearing segment and the support segment is equal to a width of the positioning segment.

In yet another embodiment the plastic sheet includes a first fabrication baseline to form the positioning segment.

In yet another embodiment the plastic sheet includes a second fabrication baseline on the support segment to form the holding section.

In yet another embodiment the plastic sheet includes a third fabrication baseline to form the bearing segment.

In yet another embodiment the bearing segment includes a detent spot at a distal end thereof.

In yet another embodiment the bearing segment includes a plurality of the retaining portions that are arranged regularly and spaced from each other at a selected interval.

In yet another embodiment the retaining portion of the bearing segment is an aperture.

In yet another embodiment the holding section includes a latch portion at a distal end thereof to couple with the retaining portion.

In yet another embodiment the keyboard includes a housing trough to store the support rack.

Through the structure set forth above, the invention, comparing with conventional structures, provides features as follows:

1. The support rack of the invention is fabricated integrally from a plastic sheet, hence does not have the problem of difficult assembly process occurred to the conventional support rack which adopts the pivotal structures.

2. The support rack of the invention can be installed on the keyboard, thus once the keyboard is carried out the support rack can be utilized for holding the wireless electronic device at any time.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a plane view of the plastic sheet of a first embodiment of the invention.

FIG. 2A is a cross section view taken on line A-A in FIG. 1.

FIG. 2B is an enlarged view of the circle area of the plastic sheet in FIG. 2A.

FIG. 3 is a schematic view of the first embodiment of the support rack when in use with a keyboard.

FIG. 4 is a schematic view of the first embodiment of the support rack when in use.

FIG. 5 is a schematic view of a second embodiment of the support rack when in use with the keyboard.

FIG. 6 is a plane view of the plastic sheet of a third embodiment of the invention.

FIG. 7 is a schematic view of the third embodiment of the support rack when in use with the keyboard.

FIG. 8 is a plane view of the plastic sheet of a fourth embodiment of the invention.

FIG. 9 is a schematic view of the fourth embodiment of the support rack when in use with the keyboard.

### DETAILED DESCRIPTION OF THE PREFERRED EMBODIMENTS

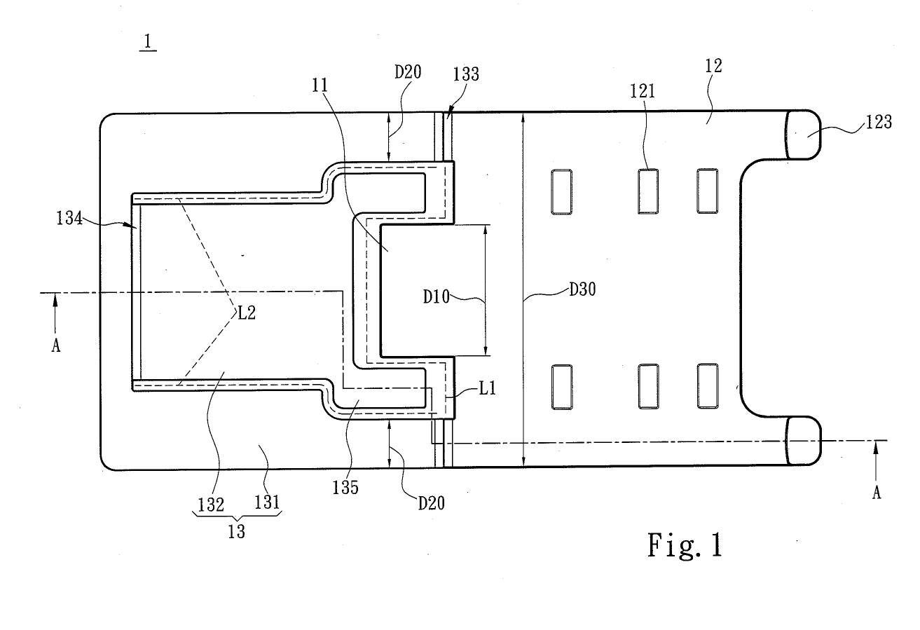

Please referring to FIG. 1, the present invention aims to provide a support rack 1 which is formed integrally from a plastic sheet. More specifically, the plastic sheet is made of flexible plastic material through a fabrication process such as injection or the like. The support rack 1 includes a positioning segment 11, a bearing segment 12 and a support segment 13. The support segment 13 further includes a leaning section 131 and a holding section 132. In one embodiment of the invention, during processing the plastic sheet to fabricate the support rack 1 a first fabrication baseline L1 is defined for forming the positioning segment 11, and a second fabrication baseline L2 is defined at a predetermined position on the plastic sheet for forming the leaning section 131 and the holding section 132. Hence, during fabrication the positioning segment 11, the bearing segment 12 and the support segment 13 can be directly formed on the plastic sheet via the first fabrication baseline L1 and the second fabrication baseline L2.

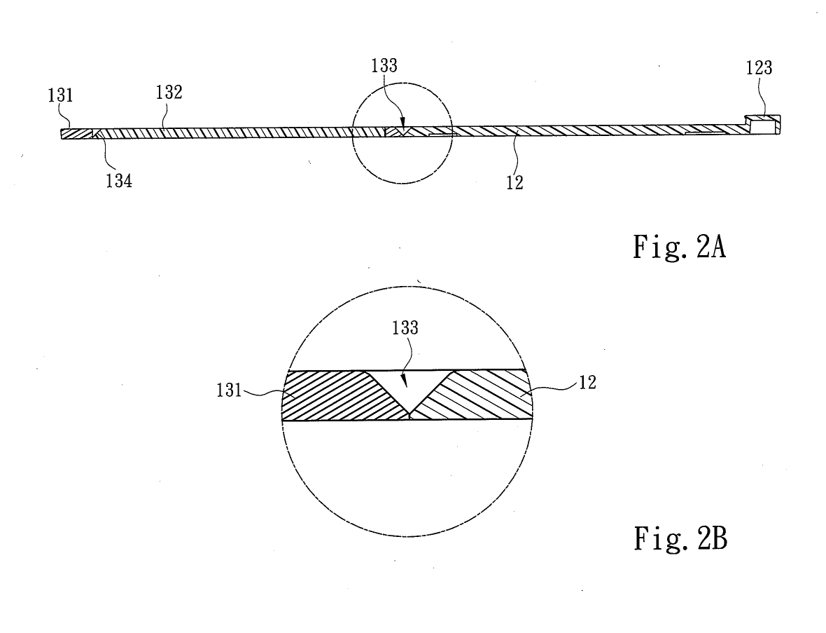

Also referring to FIGS. 2A and 2B, the support segment 13 is connected to the positioning segment 11 via the leaning section 131. A first folding notch 133 is formed at the junction of the leaning section 131 and the positioning segment 11, namely, the leaning section 131 is connected to the positioning segment 11 via the first folding notch 133. The first folding notch 133 is actually a recess formed on the surface of the plastic sheet that can be a V-shaped notch, a U-shaped notch or the like. Moreover, a second folding notch 134 is formed at the junction of the leaning section 131 and the holding section 132. The second folding notch 134 is formed like the first folding notch 133, details are omitted herein.

Furthermore, the bearing segment 12 includes at least one retaining portion 121 which allows the holding section 132 to be securely coupled with the bearing segment 12. The retaining portion 121 can be an aperture formed on the bearing segment 12, or a boss protruded from the surface of the bearing segment 12. In addition, in order to enhance the support effect of the support rack 1 when in use, in one embodiment the holding section 132 further includes a latch portion 135 formed at a distal end thereof to couple with the retaining portion 121. The latch portion 135 can further be a pin. Thus, during assembly of the support rack 1 the latch portion 135 can be inserted into the retaining portion 121 to enhance coupling of the holding section 132 and the retaining portion 121.

Please referring to FIG. 1 again, the leaning section 131 of the support segment 13 can be designed to be formed at two sides of the positioning segment 11 to make a sum of a width D10 of the positioning segment 11 and a width D20 of the support segment 13 is equal to a width D30 of the bearing segment 12.

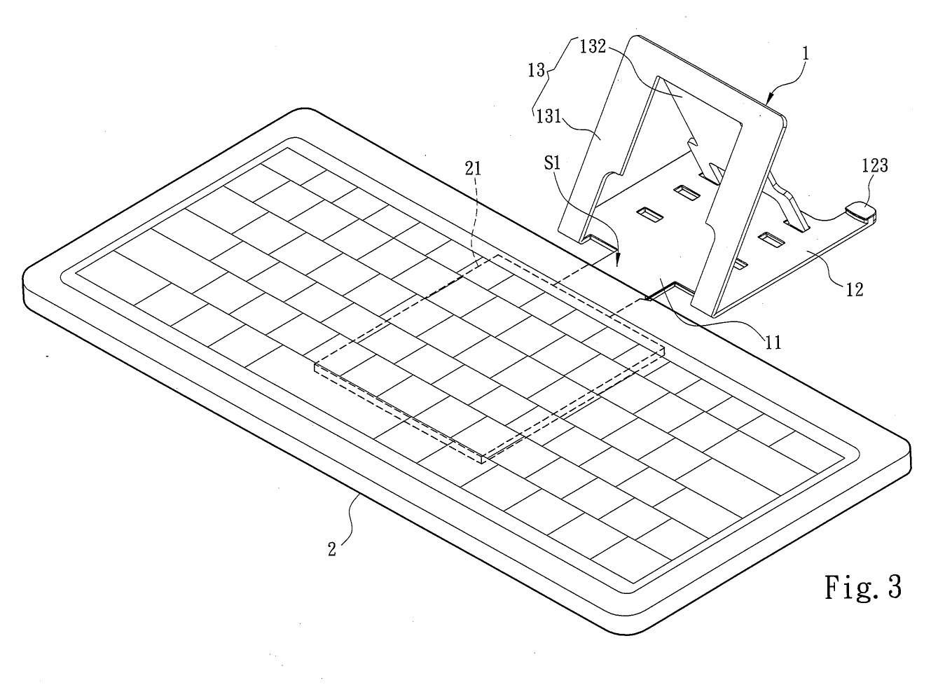

Also referring to FIGS. 1, 3 and 4, the support rack 1 of the invention can be installed on a keyboard 2 through which keying commands are input, and for a wireless electronic device to rest. More specifically, the support rack 1 is installed on one side of the keyboard 2 remote from a user that can be seen as the front side of the keyboard 2. The so called wireless electronic device (not shown in the drawings) herein can be a mobile device, a tablet computer or a portable electronic device having wireless communication function. When the support rack 1 is not in use it can be folded and held at the bottom of the keyboard 2, or be stored in a housing trough 21 which is formed on the keyboard 2 and corresponds to the support rack 1. When in use, first, placing the support rack 1 at the front side of the keyboard 2. Next, bending the leaning section 131 of the support segment 13 against the positioning segment 11 at a desired angle via the first folding notch 133, so that a holding zone S1 is formed at the positioning segment 11 to hold the wireless electronic device and the leaning section 131 is inclined for the wireless electronic device to rest. Finally, bending the holding section 132 against the leaning section 131 via the second folding notch 134 and coupling the holding section 132 with the retaining section 121 so that the holding section 132 can support the leaning section 131 and the wireless electronic device, thus finishs assembly of the support rack 1. Thereby, the user can place the wireless electronic device on the leaning section 131 and watch operation condition thereof while keying in command through the keyboard at the same time.

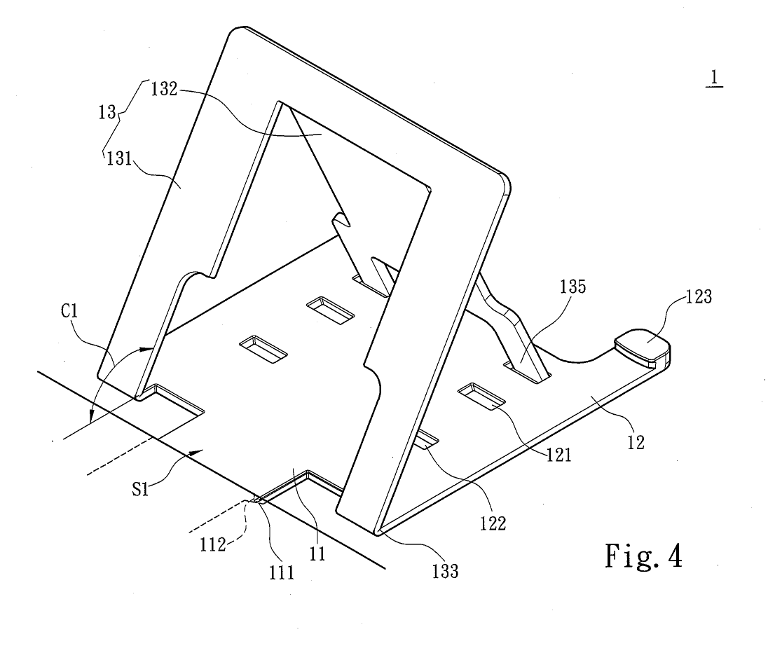

Please referring to FIG. 4, in practice a position where the retaining portion 121 is formed on the bearing segment 12 defines a support angle C1 between the leaning section 131 and the positioning segment 11. In another embodiment of the support rack 1, in order to make the support angle C1 adjustable, the bearing segment 12 is implemented by including a plurality of retaining portions 121 that are arranged regularly and spaced from each other at a selected interval. For instance, the holding section 132 can be coupled with another retaining portion 122 on the bearing segment 12 to form another support angle C1 different from that of the previous embodiment. Hence the user can engage the holding section 132 with different retaining portions 121 to generate different support angles C1 to watch the wireless electronic device at different visual angles according to requirements.

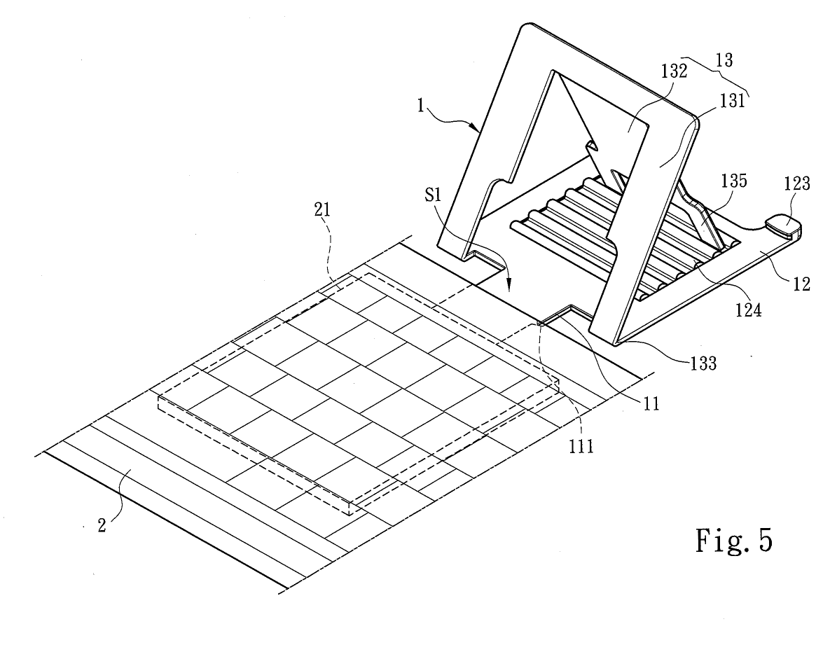

In yet another embodiment of the invention, in order to make the support rack 1 can be securely folded and held at the bottom of the keyboard 2 when not in use, the positioning segment 11 further includes a coupling section 112 which connects to the front side of the keyboard 2 and couples with the holding zone S1 via a third folding notch 111. The third folding notch 111 is formed like the first folding notch 133 previously discussed, details are omitted herein. With the third folding notch 111, the support rack 1 can be flipped against the keyboard 2 via the third folding notch 111 and then be held in the bottom or the housing trough 21 of the keyboard 2. In addition, aside from the flipping manner, the support rack 1 also can be held in the housing trough 21 in other fashions, such as providing a slide track in the housing trough 21 to enable the support rack 1 to slide against keyboard 2. When the support rack 1 is held in the housing trough 21, the user can exert a force to make the support rack 1 slide from the housing trough 21 to the front end of the keyboard 2. Then the support rack 1 can be assembled to support the wireless electronic device. Furthermore, in order to prevent the holding section 132 from inadvertently escaping the retaining portion 121 that might cause sliding and dropping of the wireless electronic device, the bearing segment 12 can further include a detent spot 123 formed at a distal end thereof. As previously discussed, FIG. 5 depicts another embodiment that the retaining portion 121 is implemented by the protrusive boss. When in use, the holding section 132 can abut the protrusive retaining portions 124 to form anchoring. The embodiment of the retaining portions 124 shown in the drawings is by no means the limitation of the invention.

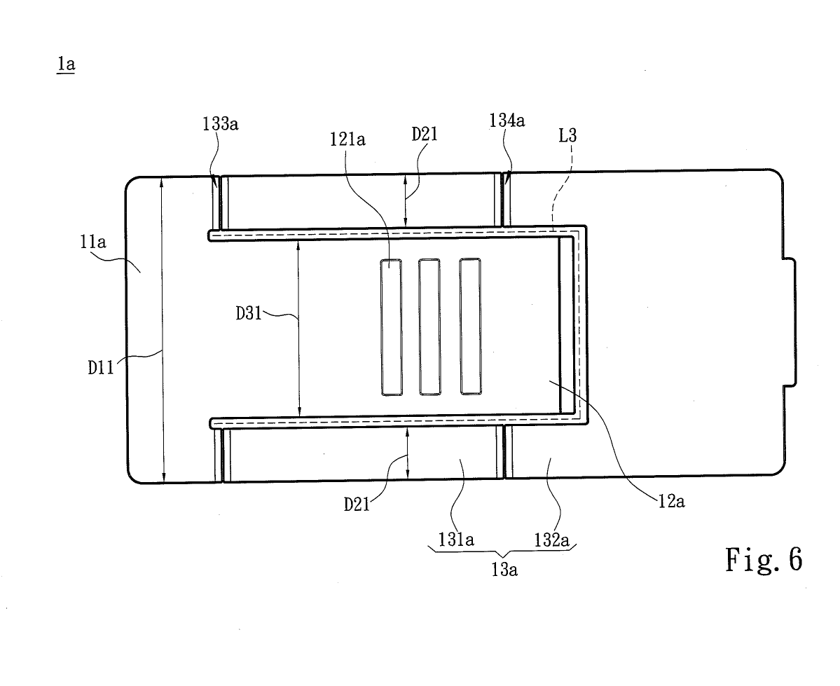

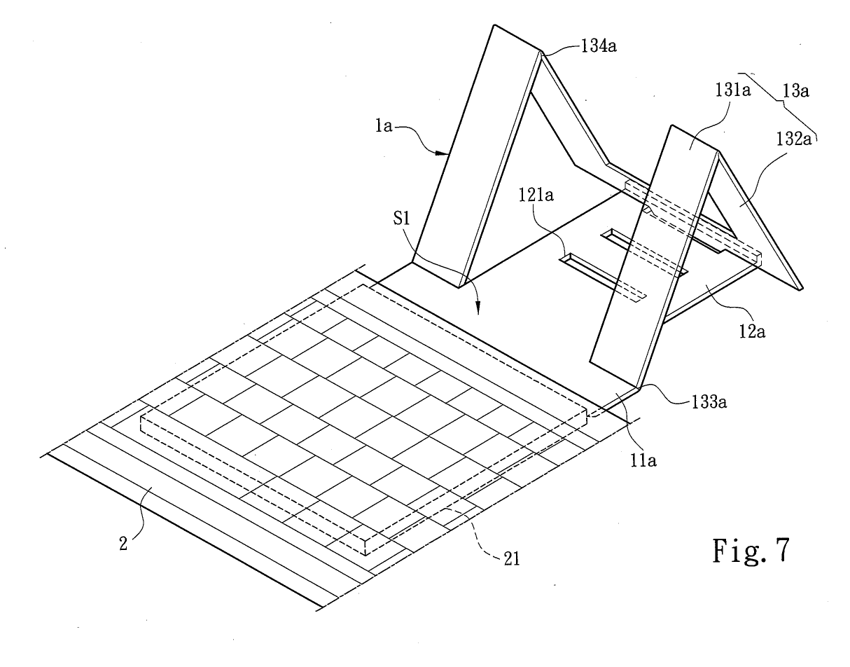

Aside from the embodiment of the support rack 1 shown in FIG. 1, other types of embodiments also can be employed. Please refer to FIG. 6 for yet another embodiment of the invention. During processing the plastic sheet a third fabrication baseline L3 is defined. After fabrication is finished based on the third fabrication baseline L3, the plastic sheet forms the positioning segment 11a, the bearing segment 12a and the support segment 13a. In this embodiment, the positioning segment 11a is formed at a width D11 equal to a sum of a width D31 of the bearing segment 12a and a width D21 of the support segment 13a. During assembly of the support rack 1a, first, bending the first folding notch 133a to flip the support segment 13a against the positioning segment 11a. Next, bending the second folding notch 134a to flip the holding section 132a against the leaning section 131a. Finally, coupling the holding section 132a with the retaining portion 121a to finish the assembly, as shown in FIG. 7.

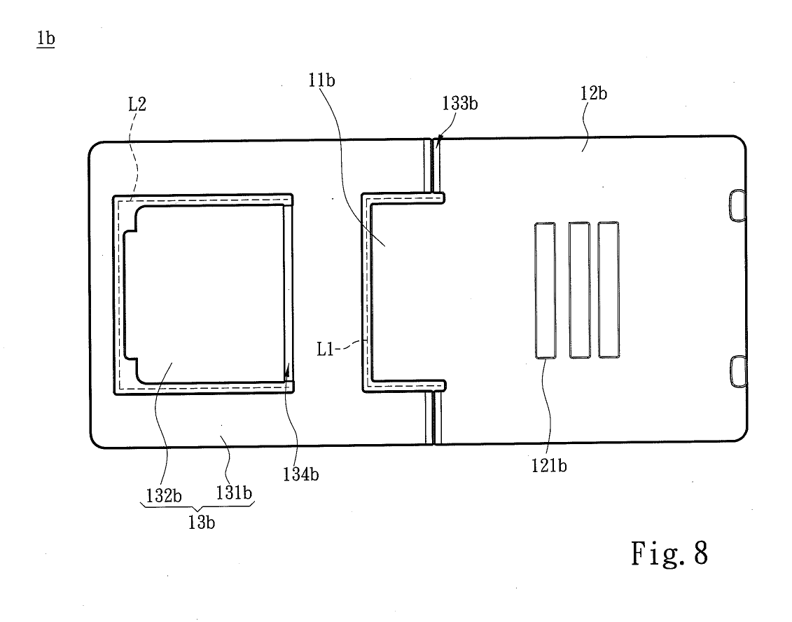

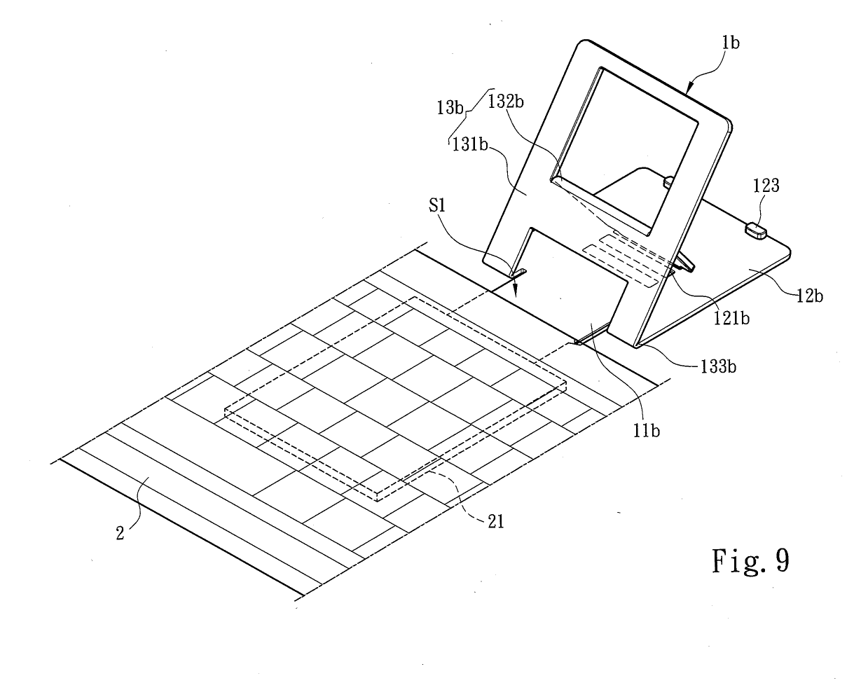

FIG. 8 illustrates yet another embodiment that the second folding notch 134b is designed to be located on the support segment 13b near the positioning segment lib. Hence the holding section 132b can be flipped against the leaning section 131b in a direction opposite to that of the embodiment depicted in FIG. 1. After the assembly is finished, the holding section 132b is still coupled with the retaining portion 121b as shown in FIG. 9. The assembly process of this embodiment is substantially same as that of the embodiment shown in FIG. 1, details are omitted herein.

As a conclusion, the support rack for a wireless electronic device of the invention can be installed on a keyboard through which keying commands can be input. The support rack is integrally fabricated from a plastic sheet and includes a positioning segment, a bearing segment and a support segment. The positioning segment is connected to the keyboard and includes a holding zone to hold the wireless electronic device. The bearing segment is connected to one side of the positioning segment opposite to the keyboard, and includes at least one retaining portion. The support segment includes a leaning section connected to the side of the positioning segment opposite to the keyboard via a first folding notch, and a holding section which is connected to the leaning section via a second folding notch and coupled with the retaining portion. Thus, by fabricating the support rack in an integrated manner the problem of complicated assembly of the pivotal structure that are implemented in the conventional support racks can be resolved. Furthermore, the support rack of the invention can be installed on the keyboard rather than be an extra accessory separated from the keyboard or the wireless electronic device that happens to the conventional support rack, thus also can overcome the drawback of inconvenient utilization.

What is claimed is:

1. A support rack for a wireless electronic device, installed on a keyboard through which keying commands are input, and integrally fabricated from a plastic sheet, comprising:
a positioning segment which is connected to the keyboard and includes a holding zone to hold a wireless electronic device;
a bearing segment which is connected to one side of the positioning segment opposite to the keyboard and includes at least one retaining portion formed thereon; and
a support segment including a leaning section which is connected to the side of the positioning segment opposite to the keyboard via a first folding notch for the wireless electronic device to rest, and a holding section which is connected to the leaning section via a second folding notch and coupled with the retaining portion to support for the support rack.

2. The support rack of claim 1, wherein the leaning section of the support segment is located at two sides of the positioning segment opposite to the keyboard.

3. The support rack of claim 2, wherein the bearing segment is formed at a width equal to a sum of widths of the positioning segment and the support segment.

4. The support rack of claim 2, wherein the positioning segment is formed at a width equal to a sum of widths of the bearing segment and the support segment.

5. The support rack of claim 1, wherein the plastic sheet includes a first fabrication baseline to form the positioning segment.

6. The support rack of claim 1, wherein the plastic sheet includes a second fabrication baseline on the support segment to form the holding section.

7. The support rack of claim 1, wherein the plastic sheet includes a third fabrication baseline to form the bearing segment.

8. The support rack of claim 1, wherein the bearing segment includes a detent spot at a distal end thereof.

9. The support rack of claim 1, wherein the bearing segment includes a plurality of the retaining portions that are arranged regularly and spaced from each other at a selected interval.

10. The support rack of claim 1, wherein the retaining portion of the bearing segment is an aperture.

11. The support rack of claim 1, wherein the holding section includes a latch portion at a distal end thereof to couple with the retaining portion.

12. The support rack of claim 1, wherein the keyboard includes a housing trough to store the support rack.
